(19) United States
(12) Patent Application Publication
(10) Pub. No.: US 2008/0283120 A1
(43) Pub. Date: Nov. 20, 2008

(54) Method of Manufacturing N-Type Multicrystalline Silicon Solar Cells

(75) Inventors: Yuji Komatsu, Alkmaar (NL); Hanno Dietrich Goldbach, Ede (NL); Rudolf Emmanuel Isidore Schropp, Driebergen (NL); Lambert Johan Geerligs, Alkmaar (NL)

Correspondence Address: FLIESLER MEYER LLP, 650 CALIFORNIA STREET, 14TH FLOOR, SAN FRANCISCO, CA, 94108, US

(73) Assignee: STICHTING ENERGIEONDERZOEK CENTRUM NEDERLAND, LE Petten (NL)

(21) Appl. No.: 12/090,249

(22) PCT Filed: Oct. 4, 2006
(86) PCT No.: PCT/NL2006/050242

§ 371 Date: Jul. 18, 2008

(30) Foreign Application Priority Data
Oct. 14, 2005 (NL) 1030200

(51) Int. Cl. H01L 31/00; H01L 21/00

(52) U.S. Cl. 136/258; 438/97; 257/E21.001

(57) ABSTRACT

The invention provides solar cells and methods of manufacturing solar cells having a Hetero-junction with Intrinsic Thin-layer (HIT) structure using an n-type multicrystalline silicon substrate. An n-type multicrystalline silicon substrate is subjected to a phosphorus diffusion step using a relatively high temperature. The front side diffusion layer is then removed. As a next step, a p-type silicon thin film is deposited at the front side of the substrate. This sequence avoids heating the p-type silicon thin film above its deposition temperature, and maintains the quality of the p-type silicon thin film.

This application claims priority to Netherlands Application No. 1030200, filed Oct. 14, 2005, and International Application No. PCT/NL2006/050242 (Publication WO 2007/043881) which are incorporated herein by reference in their entirety.

### FIELD OF THE INVENTION

The invention relates to the manufacture of solar cells. It more particularly relates to a method of manufacturing solar cells using an n-type multicrystalline silicon substrate.

### BACKGROUND

Multicrystalline silicon (mc-Si) solar cells are usually made of p-type substrate because of its longer diffusion length of the minority carrier than n-type's. The silicon feedstock for the solar cell industry largely depends on the feedstock for the Integrated Circuit (IC) industry. This is because at the manufacture of silicon, the high quality silicon is reserved for the IC industry, and the lesser quality silicon forms the feedstock for the solar cell industry. Due to a recent shortage of the whole silicon feedstock, it is desirable to utilize the n-type feedstock more effectively. In addition, solar cells made of n-type substrates may even have superior properties as compared to those made of p-type substrates, because of the relatively longer lifetime of the minority carrier in n-type silicon. However, the most effective structure and manufacturing process for n-type multicrystalline silicon solar cells are still subject to research, especially concerning the junction formation.

For single crystalline silicon solar cell made of n-type substrate, the so-called HIT (Hetero-junction with Intrinsic Thin-layer) structure was proposed and it proved to have good properties. In the HIT structure, highly doped p-type thin film is deposited on the front side (light incident side) and highly doped n-type thin film is deposited on the back side of a single crystalline silicon substrate. The thin films for both sides are deposited at a relatively low temperature less than 250° C. When applying the same technique on multicrystalline silicon substrates, it was found that the solar cell properties were unsatisfying, see “M. Taguchi, et al.”, Proceedings of 31st IEEE Photovoltaic Specialists Conference (Lake Buena Vista, Fla., 2005) p. 866-871.

Nowadays, to improve the bulk property of multicrystalline silicon substrates, a gettering process by way of phosphorus diffusion is used. This process gets rid of impurities like iron included at the process of casting the multicrystalline ingot. Hydrogen passivation by annealing after depositing the film which includes hydrogen also has an effect to improve the bulk property of multicrystalline silicon substrates.

### SUMMARY OF THE INVENTION

Both these processes have already been used in the manufacture of solar cells made of p-type multicrystalline substrates. However, there has been no proper solution for integrating these two processes into the manufacturing of a HIT structure in an n-type multicrystalline silicon substrate. This is because the thin film layer deposited on the substrate, cannot maintain its quality with high temperature process like phosphorus diffusion or hydrogen passivation.

It is an object of the present invention to manufacture a solar cell having a HIT structure using an n-type multicrystalline silicon substrate wherein the deposited thin film quality is not effected by other processing steps.

This object is achieved by a method of manufacturing a solar cell, comprising: providing a n-type multicrystalline silicon substrate having a front side and a back side; providing a phosphorus diffusion layer into the back side of the substrate; and then depositing a p-type silicon thin film on the front side.

According to the invention, the thin film heterojunction is formed after the diffusion step. Therefore, heating the p-type silicon thin film at higher temperatures than its deposition temperature can be avoided, and so the quality of the p-type silicon thin film is maintained.

In a preferred embodiment, after the step of diffusing phosphorus the method comprises: depositing a dielectric film comprising hydrogen onto the diffusion layer at the back side; annealing.

The dielectric film is deposited on the phosphorus-diffused layer. With the dielectric film, the inside reflection at the back side is improved and the current of the solar cell is increased. Due to the annealing, a hydrogen passivation is carried out. This passivation step is carried out prior to the formation of the thin film heterojunction. Therefore, heating the p-type silicon thin film at higher temperatures than its deposition temperature can be avoided, and so the quality of the p-type silicon thin film is maintained.

Preferably, the dielectric comprises SiN. If silicon nitride (SiN) is adopted for the dielectric film, the SiN can protect the phosphorus-diffused layer from a NaOH solution and a dilute fluoric acid which may be used for the pre-treatment of the formation of the thin film heterojunction.

The phosphorus diffusion layer at the back side of the substrate may be provided by first diffusing phosphorus into both sides of the substrate to render a diffusion layer on the front side and on the back side, and then removing the diffusion layer at the front side.

The invention also relates to a solar cell manufactured by the above mentioned method.

### BRIEF DESCRIPTION OF THE DRAWINGS

Further advantages and characteristics of the present invention will become clear on the basis of a description of a number of embodiments, in which reference is made to the appended drawings, in which:

FIGS. 1A-1H show an example of the practical formation of a first embodiment of this invention;

FIG. 2 shows a flow chart of a manufacturing process corresponding to the formation of FIGS. 1A-1H;

FIG. 3 shows a flow chart of a solar cell manufacturing process according to the state of the art;

FIG. 4 shows the resulting solar cell of the manufacturing process of FIG. 3;

FIG. 5 shows a flow chart of a solar cell manufacturing process according to a second embodiment of the invention;

FIG. 6 shows the resulting solar cell of the manufacturing process of FIG. 5;

FIG. 7 shows a flow chart of a manufacturing process according to a third embodiment of the invention;

FIG. 8 shows a flow chart of a manufacturing process according to a fourth embodiment of the invention.

### DETAILED DESCRIPTION OF THE INVENTION

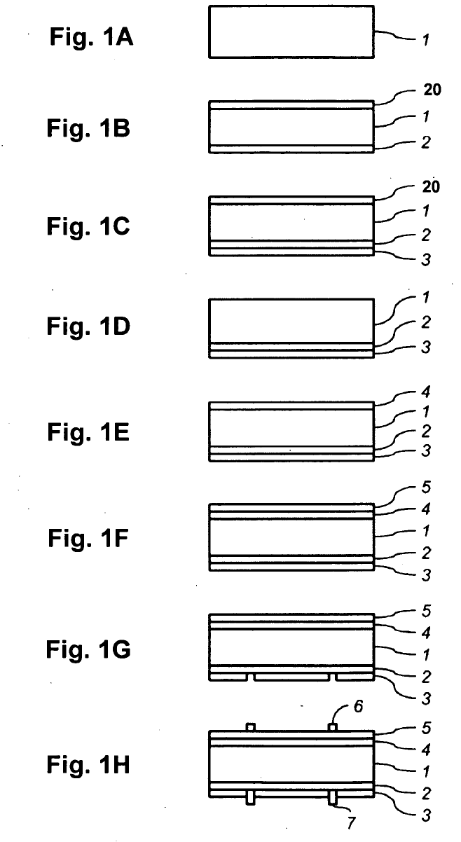

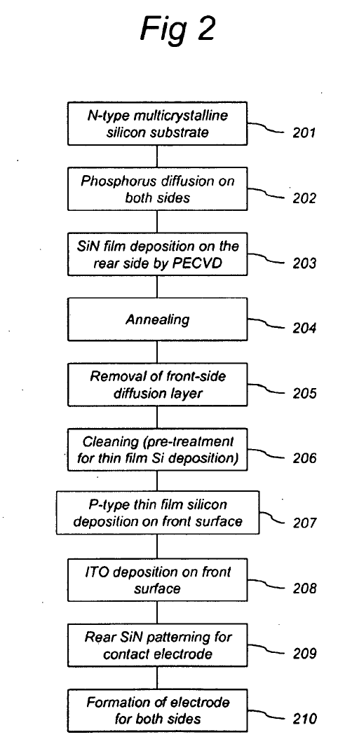

FIGS. 1A-1H show an example of a practical formation of a solar cell according to an embodiment of the invention, and FIG. 2 shows a corresponding flow chart of the manufacturing process. In a first step, a multicrystalline silicon substrate of n-type is provided, see FIG. 1A and step 201 of FIG. 2.

Then in a step 202, on both sides of the substrate 1, phosphorus diffusion layers 2, 20 are formed in for example a mixed atmosphere of N2/O2/POCl3 at temperature between for example 800-880° C. The result is shown in FIG. 1B. This diffusion may also be carried out at N2 atmosphere after coating of phosphorus glass paste. Then, in a step 203, a silicon nitride film 3 is deposited on the back side of the substrate 1 using plasma enhanced chemical vapor deposition (PECVD) at 300-500° C. with mixed gases of SiH₄/NH₃/N₂. Any type of plasma may be applicable, such like direct plasma with parallel plate, microwave remote plasma with quartz tube, expanding thermal plasma using arc discharge, etc. Hotwire CVD may also be applicable. Using these kinds of method, hydrogen is included in the silicon nitride film 3 with the content of several percentages. The result of step 203 is shown in FIG. 1C.

After the deposition of the silicon nitride film in step 203, the substrate 1 is annealed at a temperature of more than 50° C. higher than the deposition temperature, see step 204. The annealing may for example be performed at temperatures between 700-800° C. for about several seconds. Preferably, the annealing temperature does not exceed 1000° C.

Next, in a step 205, the phosphorus-diffused layer 20 on the front side is removed using for example a 10% NaOH solution at a temperature of about 90° C. The result is shown in FIG. 1D. The silicon nitride film 3 at the back side is rarely etched by the NaOH solution, consequently the phosphorus-diffused layer on the back side is protected from the NaOH solution. After the removal of the phosphorus-layer 20, the surface may be textured by a chemical solution like 3% NaOH or by another method like reactive ion etching.

Then in step 206, the front surface of the substrate is cleaned using a so-called “RCA-cleaning” for semiconductor, which includes the chemical process of NH₄OH/H₂O₂/H₂O at about 60° C., HF dip, HCl/H₂O₂/H₂O at about 70° C., and then HF dip again. This cleaning method can be more simplified, or other methods like plasma cleaning could be used.

Next in step 207, a thin film silicon layer of p-type 4, see also FIG. 1E, is deposited on the front surface using PECVD at a temperature between 150-250° C. with mixed gases of H₂/SiH₄/B₂H₆. The thin film silicon layer 4 may comprise microcrystalline silicon (μc-Si) or amorphous silicon (a-Si). Also, the thin film silicon layer 4 may comprise either a single p-type layer or multiple layers of p-type silicon and intrinsic layers. The deposition temperature may be even higher than 250° C. as long as it is lower than that of the annealing process, see step 204. The deposition method may be other like hotwire CVD.

In a step 208, an indium tin oxide (ITO) layer 5, see FIG. 1F, is deposited on the front surface with sputtering at temperatures between 150-250° C. with mixed gases of Ar/O₂ and an ITO target. Other deposition methods may be used such as vacuum evaporation methods. Alternatively, another type of transparent conductive film can be used, such as zinc oxide. Next, contact holes are formed in the silicon nitride layer 3 on the back side, using for example a photolithographic process, see FIG. 1G and step 209 of FIG. 2. Alternatively, screen printing using printable etching paste (product of Merck KGaA, Germany) can be used to make contact holes in the silicon nitride layer 3. Finally, in a step 210, front contacts 6 and back contacts 7 are formed with screen printing with silver paste. The result is shown in FIG. 1H. The firing temperature of the paste is preferably lower than that of step 207.

The process mentioned above simply represents only one example, and some parts can be substituted or enhanced by other known processing techniques. Instead of diffusing phosphorus into both sides of the substrate and then removing the diffusion layer at the front side, it is also possible to diffuse only on the back side by protecting the front side of the substrate 1 with some kind of coating and to eliminate the process of removal.

### EXAMPLES

Below, a further explanation of the invention is made using some other practical examples.

In a laboratory, 240 wafers with a thickness between 200-240 μm comprising a n-type mc-Si substrate with a resistivity of 0.5-3 ohm·cm were prepared. These wafers were sliced out from one square column with the size (width and depth) of 125×125 mm², which was cut out from one casted ingot. The wafers were numbered #1 to #240 according to the position in the original ingot. They were divided into six groups wherein every sixth wafer was placed in a specific group. Each group had 40 wafers. Hereafter, the groups are referred to as group B, group C, group D, group E, group F, group G wherein:

### Group B: #1, #7, #13, #235

### Group C: #2, #8, #14, . . . , #236

### Group D: #3, #9, #15, . . . , #237

### Group E: #4, #10, #16, . . . , #238

### Group F: #5, #11, #17, . . . , #239

### Group G: #6, #12, #18, . . . , #240.

### Example

### Group B

Group B is a typical example of the invention. The solar cells structure shown in FIG. 1H is fabricated through the processes shown in FIG. 2. The specific process condition at each process step is as follows:

Step 202: Phosphorus diffusion at the temperature of 830˜850° C. with phosphorus glass coating.
Step 203: Microwave remote plasma with quartz tube at the temperature of 350˜400° C.
Step 204: Annealing at the temperature of 650˜750° C. for 5˜20 seconds.
Step 205: Non textured surface after the removal of the front phosphorus-doped layer.
Step 206: Surface cleaning with “RCA-cleaning”.
Step 207: p-type/intrinsic a-Si deposition with the parallel plate plasma-enhanced CVD of 13.56 MHz at the temperature of 200° C. with mixed gases of SiH₄/H₂/B₂H₆.
Step 208: Magnetron sputtering of ITO at the temperature of 200° C.
Step 209: Contact patterning with screen printing using printable etching paste.
Step 210: Screen printing of silver paste and firing at 200° C.

### Example

### Group C

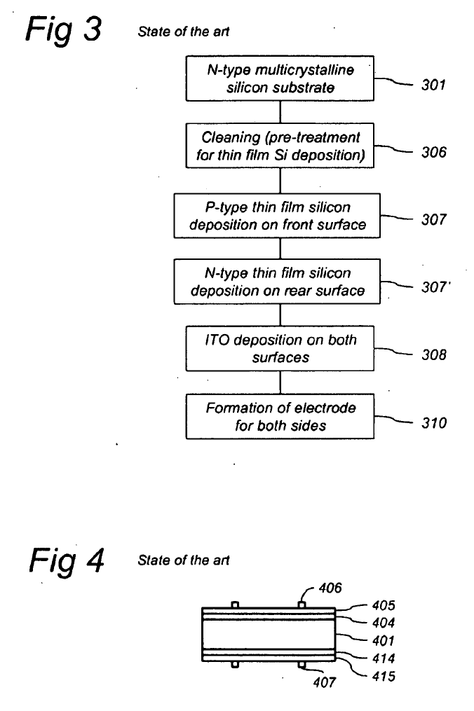

Group C was a reference group with a conventional HIT structure made by a conventional process. A flow chart of this fabricating process is shown in FIG. 3. First in a step 301, a n-type multicrystalline silicon substrate is provided. Then a cleaning step 306 follows which is the same as step 206 of FIG. 2. Next, a step 307 follows in which a p-type silicon thin film is deposited as was done in step 207 of FIG. 2. Next, in a step 307, a n-type/intrinsic a-Si deposition by way of a parallel plate plasma-enhanced CVD using 13.56 MHz at a temperature of 200° C. with mixed gases of SiH₄/H₂/PH₃ is performed. Next in a step 308, an ITO layer is deposited on both sides of the substrate. Finally, electrodes or formed on both sides, see step 310.

FIG. 4 shows the result of the processing steps of FIG. 3. The solar cell comprises a n-type multicrystalline silicon substrate 401. At the front side of the substrate, a thin film silicon layer of p-type 404 is fabricated. On top of the thin film silicon layer 404, an indium tin oxide (ITO) layer 405 is fabricated. On top of the ITO layer 405, front contact 406 are formed. At the back side of the substrate, a n-type/intrinsic a-Si thin film deposition layer 414 is fabricated. On the n-type silicon thin film deposition layer 414 an ITO layer is deposited, see layer 415.

### Example

### Group D

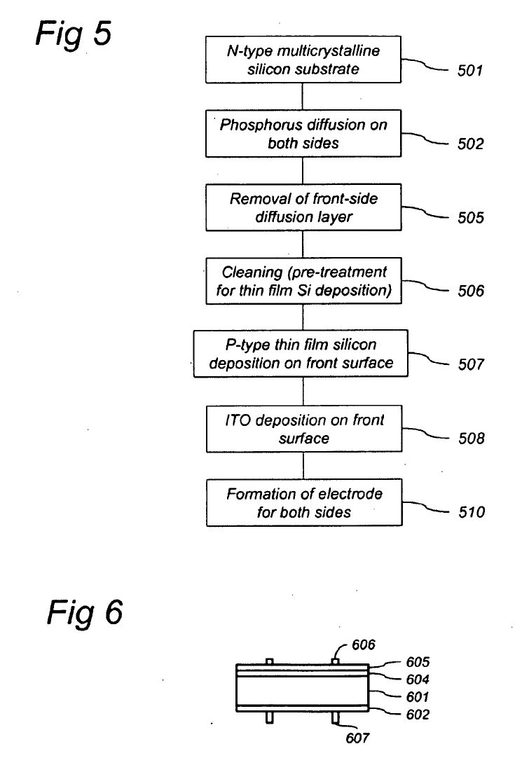

Group D is a group of solar cells fabricated according to an embodiment, where the solar cells do not have a back side silicon nitride film. The fabricating process is shown in FIG. 5. This process is simpler than that of the manufacturing process of group B because the relatively expensive SiN process is eliminated. This embodiment starts with a step 501 in which an n-type multicrystalline silicone substrate is provided. In a step 502 phosphorus diffusion layers are formed on both sides of the substrate. Next, in a step 505, the front side diffusion layer is removed. This is achieved by way of an etching method comprising the coating of the back side with a negative photo resist, such as OMR 85 (available from Tokyo Oka Kogyo Inc.), followed by the etching of the front side with a solution comprising HNO₃/HF=10:1 for a period of about 1 minute. Finally, the OMR85 is removed using OMR-remover (Tokyo Oka Kogyo Inc.). Next, a cleaning step 506 is performed identical to step 206. This step is followed by step 507 in which a p-type silicon thin film is deposited as was done in step 207, see FIG. 2. Next, a step 508 is performed which is identical to step 208. Finally, electrodes are formed on both sides, see step 510. It is noted that instead of forming a phosphorus diffusion layers on both sides of the substrate, it is possible to form the phosphor diffusion layer at only the back side, using e.g. a front-to-front configuration during the diffusion step. The front side diffusion layer will then not be formed and does not need to be removed. A cleaning step in this case is not necessary.

The resulting solar cell structure is shown in FIG. 6. The solar cell comprises a n-type multicrystalline substrate 601. At the back side a phosphorus diffusion layers 602 is formed. At the front side, a thin film silicon layer of p-type 604 is deposited forming the heterojunction. An indium tin oxide (ITO) layer 605 is deposited on the thin film silicon layer 604 at the front side. The solar cell further comprises front contacts 606 and back contacts 607.

### Example

### Group E

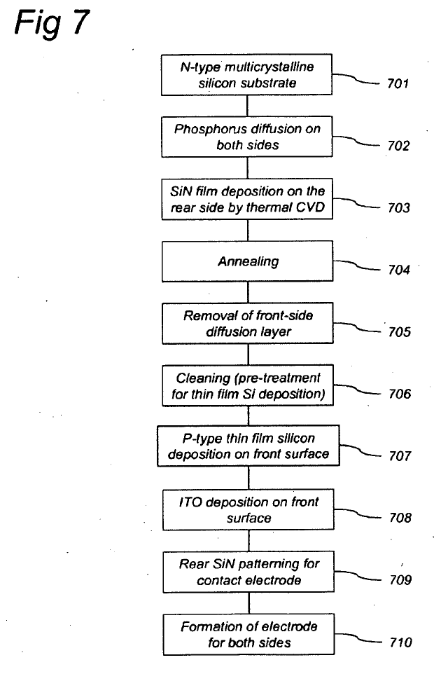

For group E, the hydrogen content in the SiN film 3 is less than 0.3 atomic %, while that of group B is between 5-10 atomic %. The hydrogen content in the SiN film 3 was determined by measuring the absorption of infrared light by Si—H and N—H bonds in the SiN film 3 using a Fourier Transform Infrared Spectrometer. A flow chart of the fabricating process is shown in FIG. 7. The specific processing steps of this embodiment are the same as those of group B, see FIG. 2, except for a step 703 and 704. In step 703, SiN is deposited with thermal CVD at a temperature of 800° C. using mixed gases of SiH4/NH3. In step 704, an annealing step is performed at a temperature between 850-900° C. for a period between 5-20 seconds.

### Example

### Group F

For group F, the hydrogen content in SiN film was between 20-25 atomic %, while that of group B was between 5-10 atomic %. The fabricating process is the same as that used for group B except for the deposition temperature at the deposition of the SiN film, see also step 203 in FIG. 2. The deposition temperature at group F is between 130-170° C.

### Example

### Group G

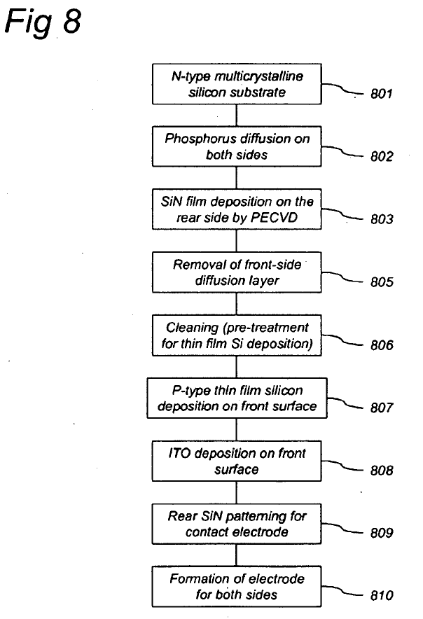

For group G, the annealing step after the SiN deposition is eliminated. A flow chart of the fabrication process is shown in FIG. 8. As compared to the flow chart of FIG. 2, step 204 is eliminated. Steps 802 to 810 are identical to steps 202 to 210, respectively.

### Example

### Results

The current-voltage characteristics of the completed cells were measured with a procedure described in IEC 60904. Table I shows the average values of the cell properties of each group, wherein Jsc is the short circuit current, Voc is the open circuit voltage and FF is the Fill Factor.

TABLE I

| | | Hydrogen | | | | | |
|---|---|---|---|---|---|---|---|
| | | in SiN | Anneal SiN | Jsc | Voc | | Efficiency |
| Group | Remark | [atomic %] | [° C.] | [mA/cm²] | [mV] | FF [%] | [%] |
| B | Typical example | 7 | 650-750 | 32.6 | 613 | 77.2 | 15.4 |
| C | Conventional HIT | — | — | 29.6 | 595 | 77.4 | 13.6 |
| D | Without back SiN | — | — | 30.5 | 605 | 77.1 | 14.2 |
| E | Low H content SiN | <0.3 | 850-900 | 31.8 | 608 | 77.1 | 14.9 |
| F | High H content SiN | 22 | 650-750 | 31.7 | 608 | 77.2 | 14.9 |
| G | Without anneal SiN | 9 | — | 31.4 | 607 | 77.2 | 14.7 |

When comparing group D with group C, it shows that the short circuit current Jsc and the open circuit voltage Voc are improved. This is most certainly due to the presence of the back side phosphorus-doped layer 2. Because of the phosphorus diffusion process, see step 202 of FIG. 2, iron contamination present in the casted wafers is gettered by diffused phosphorus atoms and as a consequence the substrate quality is improved.

When comparing group G with D, it can be seen that especially the short circuit current Jsc is improved. This is mainly due to the back side SiN film 3, see FIG. 1H. This layer enhances the inner reflection of the incident light. The same effect can be expected with other dielectric films that have similar optical properties like for example titanium oxide.

When comparing group B with E, F, and G, it is clear that both an appropriate hydrogen content and an annealing step following the SiN deposition will cause a further improvement of short circuit current Jsc and the open circuit voltage Voc. This is because the hydrogen in the SiN film 3 passivates the defect in the substrates when annealed under appropriate conditions.

This invention provides a method of manufacturing a HIT structure for multicrystalline silicon substrate made of n-type multicrystalline silicon substrates. Through the process of the phosphorus diffusion, impurities like iron included during the ingot-casting are gettered and the bulk property is improved. The phosphorus-diffused layer also serves as a back surface field to raise the voltage and a back contact with low resistivity. Preferably, the hydrogen content of the dielectric film described above is between 0.5-15%. When the dielectric film is annealed at a temperature which is more than 50° C. higher than the deposition temperature, the hydrogen in the dielectric film is emitted and penetrates in the substrate. In this way the multicrystalline silicon inside the bulk is passivated and the solar cell properties are improved.

As described above, the high temperature processes of the phosphorus diffusion, dielectric film deposition, and hydrogen passivation are carried out prior to the formation of thin film heterojunction. Therefore, heating the thin film at higher than its deposition temperature after the deposition can be avoided, and the quality of the thin film is maintained. Moreover, if silicon nitride (SiN) is adopted for the dielectric film, SiN can protect the phosphorus-diffused layer from NaOH solution and dilute fluoric acid which is required for the pre-treatment of the formation of the thin film heterojunction. Consequently, this invention makes it possible to combine the high temperature processes with the formation of a heterojunction.

With adopting the invention, the improvement of 0.6-1.8 points in the conversion efficiency can be expected compared to the conventional HIT structure of n-type multicrystalline-Si substrate.

It will be understood that variants will occur to those skilled in the art on reading the above text. Those variants are deemed to lie within the scope of the invention as described in the appended claims.

Although the present invention has been shown and described in detail with regard to only a few exemplary embodiments of the invention, it should be understood by those skilled in the art that it is not intended to limit the invention to the specific embodiments disclosed. Various modifications, omissions, and additions may be made to the disclosed embodiments without materially departing from the novel teachings and advantages of the invention, particularly in light of the foregoing teachings. Accordingly, it is intended to cover all such modifications, omissions, additions, and equivalents as may be included within the spirit and scope of the invention as defined by the following claims.

1-10. (canceled)

11. A method of manufacturing a solar cell, comprising:
(a) providing an n-type multicrystalline silicon substrate having a front side and a back side;
(b) diffusing phosphorus into both sides of said substrate to render a diffusion layer on said front side and a diffusion layer on said back side;
(c) depositing a dielectric film comprising hydrogen onto said phosphorus diffusion layer at said back side;
(d) removing said diffusion layer at said front side;
(e) texturing said front side of said substrate; and
(f) subsequent to step (e), depositing a p-type silicon thin film on said front side.

12. The method of claim 11, wherein step (e) comprises texturing said front side of said substrate using a chemical solution.

13. The method of claim 11, wherein step (e) comprises texturing said front side of said substrate using a 3% NaOH solution.

14. The method of claim 11, wherein step (e) comprises texturing said front side of said substrate using reactive ion etching.

15. The method of claim 11, wherein step (c) comprises depositing a dielectric film comprising hydrogen onto said phosphorus diffusion layer at said back side and annealing.

16. The method of claim 11, wherein step (c) comprises depositing a dielectric film comprising SiN and hydrogen onto said phosphorus diffusion layer at said back side.

17. The method of claim 11, wherein step (f) comprises subsequent to step (e), depositing a p-type silicon thin film on said front side at a temperature under 250° C.

18. A solar cell manufactured by the method of claim 11.

19. A method of manufacturing a solar cell, comprising:
(a) providing a n-type multicrystalline silicon substrate having a front side and a back side;
(b) providing a phosphorus diffusion layer at said back side of said substrate;
(c) depositing a dielectric film comprising hydrogen onto said phosphorus diffusion layer at said back side; and
(d) subsequent to steps (a), (b) and (c), depositing a p-type silicon thin film on said front side.

20. The method of claim 19, wherein step (c) comprises depositing a dielectric film comprising hydrogen onto said phosphorus diffusion layer at said back side at a deposition temperature and annealing at a temperature at least 50° C. greater than the temperature.

21. The method of claim 19, wherein step (c) comprises depositing a dielectric film comprising hydrogen onto said phosphorus diffusion layer at said back side and annealing.

22. The method of claim 19, wherein step (c) comprises depositing a dielectric film comprising SiN and hydrogen onto said phosphorus diffusion layer at said back side.

23. The method of claim 19, wherein step (c) comprises depositing a dielectric film comprising 0.5-15 atomic % hydrogen onto said phosphorus diffusion layer at said back side.

24. The method of claim 19, wherein step (d) comprises subsequent to steps (a), (b) and (c), depositing a p-type silicon thin film on said front side at a temperature under 250° C.

25. The method of claim 19, further comprising:
(e) depositing a layer of indium tin oxide on said front side;
(f) patterning said dielectric film for electrode contact; and
(g) forming electrodes on said front side and said back side.

26. The method of claim 19, wherein step (b) comprises:
(b1) diffusing phosphorus into the substrate to render a phosphorus diffusion layer on said front side and a phosphorus diffusion layer on said back side;
(b2) subsequent to step (b1) removing said phosphorus diffusion layer from said front side.

27. A solar cell manufactured by the method of claim 19.

28. A solar cell, comprising:
an n-type multicrystalline silicon substrate having a light-incident side and a back side;
a p-type silicon thin film deposited on the light-incident side of the substrate at a temperature under 250° C.;
a phosphorus diffusion layer on the back side of the substrate;
a dielectric film comprising hydrogen and SiN deposited on the phosphorus diffusion layer on the back side of the substrate and patterned for electrode contact;
one or more electrodes on the light-incident side of the substrate; and
one or more electrodes on the back side of the substrate.

29. The solar cell of claim 28, wherein the light-incident side of the n-type multicrystalline silicon substrate is textured.

30. The solar cell of claim 28, wherein the dielectric film comprises hydrogen and SiN deposited on the phosphorus diffusion layer on the back side of the substrate at a first temperature, annealed at a temperature at least 50° C. higher than the first temperature and subsequently patterned for electrode contact.
